(19) United States
(12) Patent Application Publication
(10) Pub. No.: US 2006/0073699 A1
(43) Pub. Date: Apr. 6, 2006

(54) Method for fabricating semiconductor device

(75) Inventors: Sung-Kwon Lee, Ichon-shi (KR); Min-Suk Lee, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR, INC.

(21) Appl. No.: 11/154,473

(22) Filed: Jun. 17, 2005

(30) Foreign Application Priority Data
Oct. 6, 2004 (KR) 10-2004-0079348

(51) Int. Cl. H01L 21/4763; H01L 21/31

(52) U.S. Cl. 438/639; 438/791

(57) ABSTRACT

Disclosed is a method for fabricating a semiconductor device. The method includes the steps of: forming a plurality of conductive patterns on a substrate; depositing an insulation layer on the substrate; recessing the insulation layer until a vertical height of the insulation layer becomes lower than that of the plurality of conductive patterns; forming an etch stop layer in the form of sidewalls of the conductive patterns; forming a mask pattern over the etch stop layer; and forming a plurality of contact holes such that etch profiles of the plurality of contact holes are aligned with the plurality of conductive patterns and the substrate is exposed by etching the insulation layer by using the mask pattern as an etch mask.

### FIELD OF THE INVENTION

The present invention relates to a method for fabricating a semiconductor device; and more particularly, to a method for fabricating a contact plug of a semiconductor device.

### DESCRIPTION OF RELATED ARTS

As a scale of integration of a semiconductor device has increased, a design rule has decreased. Accordingly, due to a lack in a dose, a focus and an alignment margin of a photolithography process and a limitation in an etch selectivity of an etching process, it is gradually difficult to form a fine pattern.

Furthermore, as a semiconductor device with a plurality of structures is formed and a distance between neighboring patterns decreases, an insulation property is deteriorated. Thus, a charge coupling is generated between insulation layers for insulating inter-layers from each other, and between the neighboring patterns. The charge coupling makes it impossible to obtain an operation property required by a device.

In order to improve the aforementioned problems, a self align contact (SAC) etching process using a difference in an etch selectivity of bottom layers and obtaining an etch profile to make a bottom pattern structure automatically aligned is widely used at the present time.

During performing the SAC etching process, a difference between an etch selectivity of a nitride based layer used as a material to form a hard mask or an etch stop layer and that of an oxide based layer used as a material to form an inter-layer insulation layer is used.

However, due to an increase in an aspect ratio based on an increase of the scale of integration, it becomes difficult to produce a desirable pattern by only using the SAC etching process.

FIG. 1 is a photograph of scanning electron microscopy (SEM) illustrating a SAC fail.

Referring to FIG. 1, a field oxide layer 101 is formed on a substrate, thereby defining an active region 102. A plurality of gate electrode patterns formed by stacking a gate oxide layer 103, a polysilicon layer 104, a tungsten layer 105 and a hard mask 106 are formed on the substrate.

A plurality of cell contact plugs 107 electrically contacted to an impurity diffusion region (not shown) of the substrate are formed between each of the gate electrode patterns. Some portions of the cell contact plugs 107 are electrically contacted to a bit line 109 and other portions of the cell contact plugs 107 are electrically contacted to a contact plug 110 for a storage node.

However, as described above, as a scale of integration increases, an etch target increases during performing the SAC etching process due to an increase in the aspect ratio.

Accordingly, an attack is generated in shoulder portions of the gate electrode patterns, i.e., the hard mask 106.

The attack generated in the hard mask 106 brings degradation of an insulation property between a gate conductive layer and the cell contact plug 107, between the gate conductive layer and the bit line 109, or between the gate conductive layer and the contact plug 110 for the storage node. Also, the excessive attack exposes the gate conductive layer, thereby inducing an electric short between the aforementioned layers.

A reference numeral 108 shown in FIG. 1 illustrates the electric short generated between the tungsten layer 105 used as the gate conductive layer and the contact plug 110 for the storage node.

### SUMMARY OF THE INVENTION

It is, therefore, an object of the present invention to provide a method for fabricating a semiconductor device capable of preventing degradation from being generated in an insulation property between neighboring patterns due to a self align contact (SAC) fail.

In accordance with one aspect of the present invention, there is provided a method for fabricating a semiconductor device, including the steps of: forming a plurality of conductive patterns on a substrate; depositing an insulation layer on the substrate; recessing the insulation layer until a vertical height of the insulation layer becomes lower than that of the plurality of conductive patterns; forming an etch stop layer in the form of sidewalls of the conductive patterns; forming a mask pattern over the etch stop layer; and forming a plurality of contact holes such that etch profiles of the plurality of contact holes are aligned with the plurality of conductive patterns and the substrate is exposed by etching the insulation layer by using the mask pattern as an etch mask.

In accordance with another aspect of the present invention, there is provided a method for fabricating a semiconductor device, including the steps of: forming a plurality of conductive patterns on a substrate; forming a first etch stop layer along a profile provided with the plurality of conductive patterns; depositing an insulation layer on the first etch stop layer; recessing the insulation layer whose vertical height is lower than the plurality of conductive patterns; forming a second etch stop layer in the form of sidewalls of the conductive patterns; forming a mask pattern over the second etch stop layer; and forming a plurality of contact holes by etching the insulation layer and the first etch stop layer by using the mask pattern as an etch mask such that etch profiles of the plurality of contact holes are aligned with the plurality of conductive patterns and the substrate is exposed.

### BRIEF DESCRIPTION OF THE DRAWINGS

The above and other objects and features of the present invention will become better understood with respect to the following description of the preferred embodiments given in conjunction with the accompanying drawings, in which:

FIG. 1 a photograph of scanning electron microscopy (SEM) illustrating a conventional self align contact (SAC) fail; and

FIGS. 2A to 2F are cross-sectional views illustrating a process for forming a cell contact hole in accordance with the present invention.

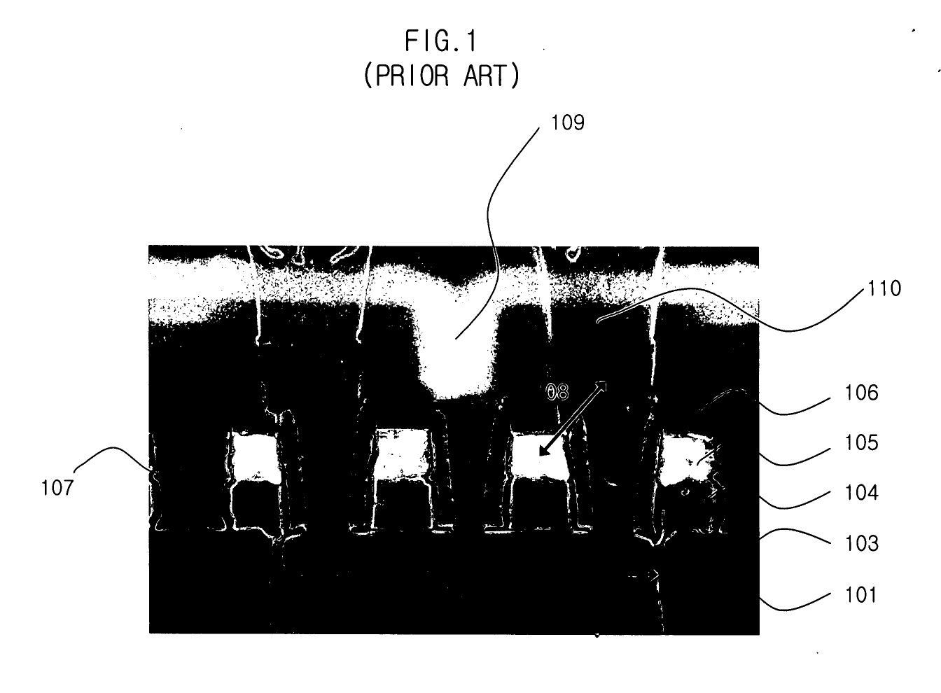

### DETAILED DESCRIPTION OF THE INVENTION

Hereinafter, detailed descriptions of preferred embodiments of the present invention will be provided with reference to the accompanying drawings.

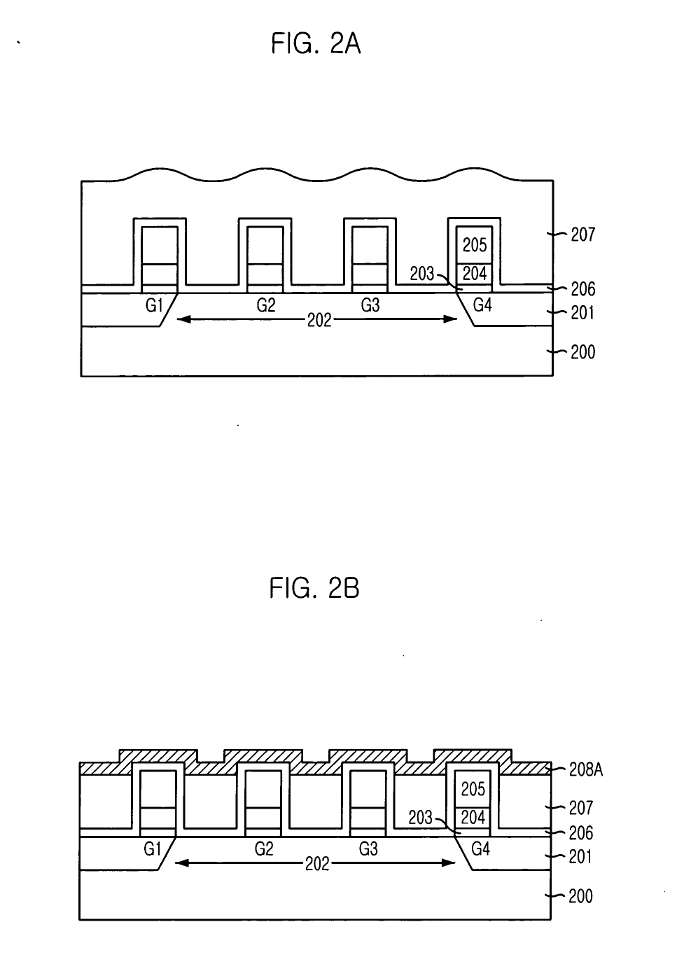

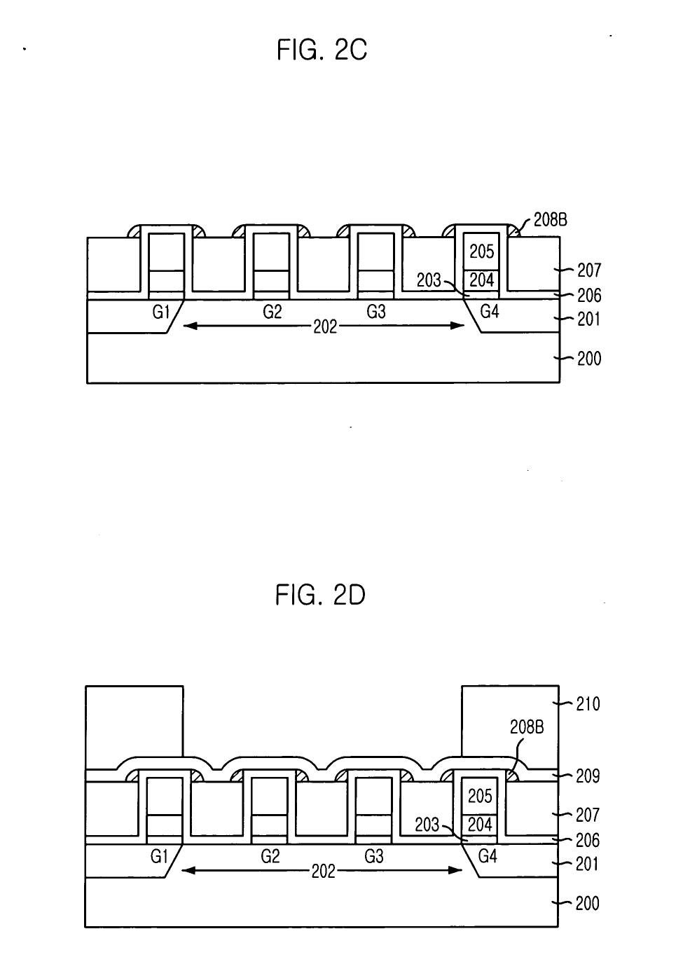

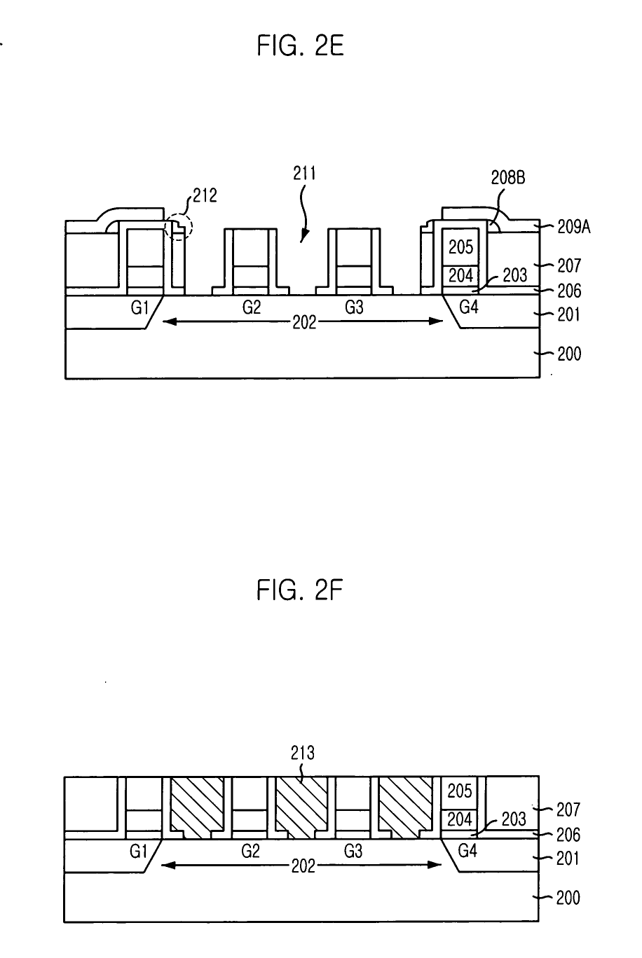

FIGS. 2A to 2F are cross-sectional views illustrating a process for forming a cell contact hole in accordance with the present invention.

As shown in FIG. 2A, a field oxide layer 201 is partially formed on a substrate 200, thereby defining a field region and an active region 202.

Subsequently, a plurality of gate electrode patterns G1, G2, G3 and G4 formed by stacking a gate insulation layer 203, a gate conductive layer 204 and a gate hard mask 205 are formed on the substrate 200 provided with various elements such as a well.

Herein, the gate insulation layer 203 is made of a typical oxide based layer such as a silicon oxide layer and the gate conductive layer 204 is formed in single or in combination of polysilicon, tungsten (W), tungsten nitride (WN), tungsten silicide (WSiₓ).

The gate hard mask 205 serves a role in preventing an attack caused by the gate conductive layer 204 during a self align contact (SAC) etching process for forming a subsequent contact and making it possible to form a SAC etch profile. Thus, the gate hard mask 205 uses a material whose etch speed is greatly different from that of an inter-layer insulation layer. For instance, in case of using an oxide based layer for forming the inter-layer insulation layer, a nitride based layer such as a silicon nitride (SiN) layer or a silicon oxynitride (SiON) layer is used. In case of using a polymer based low-k dielectric layer for forming the inter-layer insulation layer, an oxide based layer is used.

An impurity diffusion region (not shown) such as a source/drain junction is formed on the substrate 200 between the gate electrode patterns G1, G2, G3 and G4.

Next, spacers (not shown) are formed along a profile provided with the gate electrode patterns G1, G2, G3 and G4. Then, a first etch stop layer 206 is formed on an entire surface where the spacers are formed. The first etch stop layer 206 serves a role in preventing an attack on a lower structure such as the spacers and the gate electrode patterns G1, G2, G3 and G4 during an etching process employing a subsequent SAC process. At this time, it is preferable to form the first etch stop layer 206 along the profile of the lower structure and a nitride based material layer is used for forming the first etch stop layer 206.

The first etch stop layer 206 is deposited in a different thickness according to a contact critical dimension (CD). However, it is preferable to deposit the first etch stop layer 206 in a thickness ranging from approximately 100 Å to approximately 300 Å.

Next, an oxide based inter-layer insulation layer 207 is formed on an upper portion provided with the first etch stop layer 206.

In case of using the oxide based layer for forming the inter-layer insulation layer 207, a material selected from a group consisting of a borosilicateglass (BSG) layer, a borophosphosilicateglass (BPSG) layer, a phosphosilicateglass (PSG) layer, a tetraethylorthosilicate (TEOS) layer, a high density plasma (HDP) oxide layer, a spin-on-glass (SOG) layer and an advanced planarization layer (APL) is used. In addition to the oxide based layer, an inorganic or organic based low-k dielectric layer can be used.

As shown in FIG. 2B, a planarization process performed for a removal of a height difference in an upper portion of the inter-layer insulation layer 207 and a planarization of the inter-layer insulation layer 207 is excessively employed, thereby recessing the inter-layer insulation layer 207 to reduce a vertical height of the inter-layer insulation layer 207 compared with that of the gate electrode patterns G1, G2, G3 and G4.

At this time, a blanket-etch process or a chemical mechanical polishing (CMP) process is employed. Also, there is another possibility that the CMP process is first performed and then, the inter-layer insulation layer 207 is recessed by using one of a diluted solution of hydrogen fluoride (HF) and a solution of buffered oxide etchant (BOE).

During employing the blanket-etch process, it is possible to employ a plasma etch to recess a predetermined portion of the inter-layer insulation layer 207.

In case of recessing the predetermined portion of the inter-layer insulation layer 207, the inter-layer insulation layer 207 is additionally recessed in a depth ranging from approximately 200 Å to approximately 1,000 Å from surfaces of the gate patterns.

Along an entire profile where the inter-layer insulation layer 207 is recessed, a second etch stop layer 208A is deposited in a thickness ranging from approximately 50 Å to approximately 500 Å.

The second etch stop layer 208A includes a nitride based insulation layer selected from a group consisting of a silicon nitride (SiN) based insulation layer, a silicon oxynitride (SION) layer and a silicon-rich oxynitride (SRON) layer.

It is preferable to employ one of a low pressure chemical vapor deposition (LPCVD) method, an atomic layer deposition (ALD) method and a plasma enhanced chemical vapor deposition (PECVD) method to maximize an etch selectivity of the second etch stop layer 208A to an oxide based layer.

As shown in FIG. 2C, a blanket-etch process is employed to the second etch stop layer 208A. Herein, the etch stop layer 208A subjected to the blanket-etch process is denoted as a reference numeral 208B. Thus, the second etch stop layer 208B becomes to have a spacer type which the second etch stop layer 208B is expanded into the recessed inter-layer insulation layer 207 at each shoulder portion of the gate electrode patterns G1, G2, G3 and G4.

At this time, a dry etch employing a plasma is used. The first etch stop layer 206 is etched and thus, the gate hard mask 205 can be exposed or some portions of the first etch stop layer 206 can remain.

As shown in FIG. 2D, a material layer 209 for a sacrificial hard mask is deposited on the second etch stop layer 208B in the form of spacer. A photoresist pattern 210 for a cell contact plug formation is formed on the material layer 209 for the sacrificial hard mask.

The material layer 209 for the sacrificial hard mask is used for the purpose of securing an etch tolerance of the photoresist pattern due to a limitation in a resolution during performing a photolithography process and preventing a pattern deformation. A material selected from a group consisting of a tungsten layer, a polysilicon layer, an amorphous carbon layer, an oxynitride layer and a nitride layer is mainly used as the sacrificial hard mask.

Meanwhile, during forming the photoresist pattern 210, an anti-reflective coating layer can be used between the photoresist pattern 210 and a lower structure of the photoresist pattern 210 for the purpose of preventing an undesirable pattern formation from a scattered reflection due to a high degree of light reflection during a photo-exposure process for a pattern formation and improving an adhesiveness between the photoresist pattern 210 and the lower structure of the photoresist pattern 210. At this time, the anti-reflective coating layer mainly uses an organic based material having a similar etch property with the photoresist pattern 210. However, according to a process, the anti-reflective coating layer can be omitted.

More specific to the process for forming the photoresist pattern 210, a photoresist for ArF or F₂ light source, e.g., COMA or acrylaid which is the photoresist for ArF light source, is coated on the lower structure of the anti-reflective coating layer or the material layer 209 for the sacrificial hard mask in a predetermined thickness by performing a spin coating method. Afterwards, predetermined portions of the photoresist are selectively photo-exposed by using ArF or F₂ light source and a predecided reticle (not shown) for defining a width of a contact hole. Thereafter, a developing process proceeds by making a photo-exposed portion or a non-photo-exposed portion remain, and a cleaning process is then performed to remove etch remnants, thereby forming the photoresist pattern 210 which is a cell contact open mask.

As shown in FIG. 2E, the material layer 209 for the hard mask is etched by using the photoresist pattern 210 as an etch mask, thereby forming a sacrificial hard mask 209A defining a contact hole region for a storage node. Subsequently, the photoresist pattern 210 is removed.

In case of using an organic based anti-reflective coating layer, the anti-reflective coating layer is simultaneously removed during performing a photoresist strip process for a removal of the photoresist pattern 210.

A self align contact (SAC) etching process etching the inter-layer insulation layer 207 by using the sacrificial hard mask 209A as an etch mask is performed and then, the SAC etching process is stopped at the first etch stop layer 206. Afterwards, the first etch stop layer 206 is removed, thereby forming a plurality of contact hole 211 exposing an impurity diffusion region of the substrate 200

During performing the SAC etching process, a typical recipe for the SAC etching process is employed. That is, a fluoride based plasma, e.g., CₓF_{y} (x and y range from approximately 1 to approximately 10) gas such as tetrafluoroethylene (C₂F₄), hexafluoroethane (C₂F₆) octofluoropropane (C₃F₈), hexafluorobutadiene (C₄F₆), octafluorocyclopentene (C₅F₈) or perfluorocyclopentane (C₅F₁₀) is used as a main etch gas along with an additional CₐH_{b}F_{c} (a, b and c range from approximately 1 to approximately 10) gas such as difluoromethane (CH₂F₂), trifluoromethyl acetylene (C₃HF₅) or trifluoromethane (CHF₃). At this time, an inert gas such as helium (He), neon (Ne), argon (Ar) or xenon (Xe) is used as a carrier gas.

In case of the sacrificial hard mask 209A, the sacrificial hard mask 209A is removed after a contact open process or during a plug isolation process.

During performing the SAC etching process, an etch target increases and thus, although the SAC etching process is excessively employed, the spacer type second etch stop layer 208B performs a role of an etch stop. Accordingly, an attack is not generated on each of the shoulder portions 212 of the gate electrode patterns G1, G2, G3 and G4.

Next, in order to expand a critical dimension (CD) in a lower portion of the contact hole 211, an additional etching process is employed for approximately 10 seconds to approximately 5 minutes. At this time, a solution of HF diluted with a solution of BOE or pure water by approximately 100-fold to approximately 1,000-fold is used.

Subsequently, to remove the interface oxide layer formed on a lower portion of the contact hole 211 and the foreign body, a cleaning process is performed before the conductive layer for forming the plug is deposited. At this time, a solution of BOE or HE is used. It is necessary to use the solution of HF diluted with the pure water by approximately 100-fold to approximately 1,000-fold.

As shown in FIG. 2F, a conductive layer for forming a plug is deposited on an entire surface, thereby filling the plurality of contact holes 211. Afterwards, a plug planarization process is employed until the inter-layer insulation layer 207 and the gate hard mask 205 are exposed, thereby forming a plurality of cell contact plugs 213.

As described above, in accordance with the present invention, the inter-layer insulation layer is recessed to make a height of the inter-layer insulation layer lower than that of the gate electrode patterns and the second etch stop layer with the spacer type expanded into the recessed inter-layer insulation layer fro the upper portion of the gate electrode patterns is formed, thereby protecting the shoulder portions of the gate electrode patterns. Accordingly, during the SAC etching process, it should be noted that the attack generated on the shoulder portions of the gate electrode patterns can be prevented.

In accordance with the present invention, although it is exemplified that the mask pattern for the contact hole for the storage node is either a line type or T-type, other various types such as a hole type can also be applied to the present invention.

Furthermore, in accordance with the present invention, although the process for forming the cell contact plug contacted to the substrate between the plurality of gate electrode patterns is exemplified, a process for forming various types of contact plugs such as a contact plug for a storage node can also be applied to the present invention.

As described above, the present invention prevents the attack generated on the shoulder portions of the conductive patterns due to the SAC fail during forming the contact plug, thereby providing an effect of improving yields of devices.

The present application contains subject matter related to the Korean patent application No. KR 2004-0079348, filed in the Korean Patent Office on Oct. 6, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a semiconductor device, comprising the steps of:
forming a plurality of conductive patterns on a substrate;
depositing an insulation layer on the substrate;
recessing the insulation layer until a vertical height of the insulation layer becomes lower than that of the plurality of conductive patterns;
forming an etch stop layer in the form of sidewalls of the conductive patterns;
forming a mask pattern over the etch stop layer; and
forming a plurality of contact holes such that etch profiles of the plurality of contact holes are aligned with the plurality of conductive patterns and the substrate is exposed by etching the insulation layer by using the mask pattern as an etch mask.

2. The method of claim 1, wherein the step of recessing the insulation layer is performed through a method selected from a group consisting of singly using a chemical mechanical polishing (CMP) process, using one of a diluted solution of hydrogen fluoride (HF) and a solution of buffered oxide etchant (BOE) after performing the CMP process, and using a blanket-etch to recess a predetermined portion of the insulation layer.

3. The method of claim 2, wherein in case of recessing the predetermined portion of the insulation layer, the insulation layer is additionally recessed in a depth ranging from approximately 200 Å to approximately 1,000 Å from surfaces of the conductive patterns.

4. The method of claim 1, wherein the etch stop layer is a nitride based insulation layer selected from a group consisting of a silicon nitride (SiN) based insulation layer, a silicon oxynitride (SiON) layer and a silicon-rich oxynitride (SRON) layer.

5. The method of claim 4, wherein the etch stop layer is formed through one of a low pressure chemical vapor deposition (LPCVD) method, an atomic layer deposition (ALD) method and a plasma enhanced chemical vapor deposition (PECVD) method.

6. A method for fabricating a semiconductor device, comprising the steps of:
forming a plurality of conductive patterns on a substrate;
forming a first etch stop layer along a profile provided with the plurality of conductive patterns;
depositing an insulation layer on the first etch stop layer;
recessing the insulation layer whose vertical height is lower than the plurality of conductive patterns;
forming a second etch stop layer in the form of sidewalls of the conductive patterns;
forming a mask pattern over the second etch stop layer; and
forming a plurality of contact holes by etching the insulation layer and the first etch stop layer by using the mask pattern as an etch mask such that etch profiles of the plurality of contact holes are aligned with the plurality of conductive patterns and the substrate is exposed.

7. The method of claim 6, wherein the step of recessing the insulation layer is performed through a method selected from a group consisting of singly using a chemical mechanical polishing (CMP) process, using one of a diluted solution of hydrogen fluoride (HF) and a solution of buffered oxide etchant (BOE) after performing the CMP process, and using a blanket-etch to recess a predetermined portion of the insulation layer.

8. The method of claim 7, wherein in case of recessing the predetermined portion of the insulation layer, the insulation layer is additionally recessed in a depth ranging from approximately 200 Å to approximately 1,000 Å from surfaces of the conductive patterns.

9. The method of claim 6, wherein the first and the second etch stop layers are nitride based insulation layers selected from a group consisting of a silicon nitride (SiN) based insulation layer, a silicon oxynitride (SION) layer and a silicon-rich oxynitride (SRON) layer.

10. The method of claim 9, wherein the second etch stop layer is formed through one of a low pressure chemical vapor deposition (LPCVD) method, an atomic layer deposition (ALD) method and a plasma enhanced chemical vapor deposition (PECVD) method.

11. The method of claim 1, wherein the mask pattern includes a structure selected from a group consisting of a photoresist pattern, a photoresist pattern/an anti-reflective coating layer, a photoresist pattern/a sacrificial hard mask and a photoresist pattern/an anti-reflective coating layer/a sacrificial hard mask.

12. The method of claim 6, wherein the mask pattern includes a structure selected from a group consisting of a photoresist pattern, a photoresist pattern/an anti-reflective coating layer, a photoresist pattern/a sacrificial hard mask and a photoresist pattern/an anti-reflective coating layer/a sacrificial hard mask.

13. The method of claim 11, wherein the sacrificial hard mask includes a layer selected from a group consisting of a nitride layer, an oxynitride layer, a tungsten layer, a polysilicon layer and an amorphous carbon layer.

14. The method of claim 12, wherein the sacrificial hard mask includes a layer selected from a group consisting of a nitride layer, an oxynitride layer, a tungsten layer, a polysilicon layer and an amorphous carbon layer.

15. The method of claim 11, wherein a photolithography process employing an ArF or a F₂ light source is used for forming the photoresist pattern.

16. The method of claim 12, wherein a photolithography process employing an ArF or a F₂ light source is used for forming the photoresist pattern.

17. The method of claim 1, wherein the insulation layer includes an oxide layer.

18. The method of claim 6, wherein the insulation layer includes an oxide layer.

19. The method of claim 17, wherein the step of forming the plurality of contact holes employs a self align contact (SAC) etching process.

20. The method of claim 18, wherein the step of forming the plurality of contact holes employs a SAC etching process.

21. The method of claim 17, wherein at the step of forming the plurality of contact holes, a CₓF_{y} (x and y range from approximately 1 to approximately 10) gas is used as a main etch gas along with an additional CₐH_{b}F_{c} (a, b and c range from approximately 1 to approximately 10) gas and an inert gas such as He, Ne, Ar or Xe is used as a carrier gas.

22. The method of claim 18, wherein at the step of forming the plurality of contact holes, a CₓF_{y} (x and y range from approximately 1 to approximately 10) gas is used as a main etch gas along with an additional CₐH_{b}F_{c} (a, b and c range from approximately 1 to approximately 10) gas and an inert gas such as He, Ne, Ar or Xe is used as a carrier gas.
